(19) United States
(12) Patent Application Publication
(10) Pub. No.: US 2014/0048934 A1
(43) Pub. Date: Feb. 20, 2014

(54) METHOD TO CONTROL UNDERFILL FILLET WIDTH

(71) Applicants: Meng-Tse Chen, Changzhi Township (TW); Jung Wei Cheng, Hsin-Chu (TW); Chun-Cheng Lin, New Taipei City (TW); Yu-Peng Tsai, Taipei City (TW); Ming-Da Cheng, Jhubei City (TW); Chung-Shi Liu, Hsin-Chu (TW)

(72) Inventors: Meng-Tse Chen, Changzhi Township (TW); Jung Wei Cheng, Hsin-Chu (TW); Chun-Cheng Lin, New Taipei City (TW); Yu-Peng Tsai, Taipei City (TW); Ming-Da Cheng, Jhubei City (TW); Chung-Shi Liu, Hsin-Chu (TW)

(73) Assignee: TAIWAN SEMICONDUCTOR MANUFACTURING COMPANY, LTD., Hsin-Chu (TW)

(21) Appl. No.: 13/586,564

(22) Filed: Aug. 15, 2012

(51) Int. Cl. H01L 23/498; H01L 21/56

(52) U.S. Cl. 257/738; 438/127; 257/E21.502; 257/E23.01; 257/E23.069

(57) ABSTRACT

A semiconductor device assembly includes a substrate having an area of the surface treated to form a surface roughness. A die is mounted on the substrate by a plurality of coupling members. An underfill substantially fills a gap disposed between the substrate and the die, wherein a fillet width of the underfill is substantially limited to the area of surface roughness.

### BACKGROUND

When a semiconductor device such as an integrated circuit (IC) chip is assembled on a substrate, the chip is spaced apart from the substrate by solder bumps, thereby forming a gap between the chip and the substrate. It is well known that there is a significant difference between the coefficients of thermal expansion (CTE) of the chip and the substrate. As a consequence of this CTE difference, thermomechanical stresses are created at the solder interconnections, especially in the regions of the joints, when the assembly is subjected to temperature cycling during device usage or reliability testing. These stresses tend to fatigue the joints and the bumps, resulting in cracks and eventual failure of the assembly.

In order to distribute the mechanical stress and to strengthen the solder joints without affecting the electrical connection, the gap between the IC chip and the substrate is customarily filled with a polymer material referred to as an “underfill.” The underfill is dispensed onto the substrate adjacent to the IC chip, which then starts to spread out and move by capillary forces (referred to as “bleed out”) to fill the gap and encapsulate the solder bumps.

However, traditional tools and methods for underfilling may result in producing over encapsulated and/or under encapsulated underfill fillets resulting in higher stress concentration. For example, the fillet width on one side of the die may be wider than the fillet width on the other side. Similarly, the fillet height on one side of the die may be higher than the fillet height on the other side of the die. These unbalanced underfill fillets can cause high stress concentration to the die. Also, the traditional tools and methods for underfilling may be inadequate to handle bleed out of the underfill, which may be undesirable. Bleed out is essentially a wetting phenomenon. Curing does not change the degree of spread since the spreading occurs primarily prior to curing. If the areas surrounding the chip have other components attached, such as the peripheral joints of neighboring devices (e.g., solder bumps, solder balls, metal pillars, or the like) or other passive devices, it may be preferable not to have the underfill touch those components.

### BRIEF DESCRIPTION OF DRAWINGS

Embodiments of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart of a method for underfilling a gap disposed between a substrate and a die of a semiconductor device assembly, according to an embodiment of the present disclosure;

FIG. 2 is a flowchart of a method for packaging a semiconductor device, according to an embodiment of the present disclosure;

FIG. 3 is a cross-sectional view of a semiconductor device assembly undergoing a process of forming a surface roughness on a substrate prior to dispensing an underfill for filling a gap, according to an embodiment of the present disclosure;

FIG. 4 is a top view of a semiconductor device assembly described with reference to FIG. 3;

FIG. 5 is a cross-sectional view of a semiconductor device assembly described with reference to FIG. 3 undergoing a process of dispensing an underfill for filling a gap, according to an embodiment of the present disclosure; and

FIG. 6 is a top view of a semiconductor device assembly described with reference to FIG. 5.

### DETAILED DESCRIPTION

In the following description, specific details are set forth to provide a thorough understanding of embodiments of the present disclosure. However, one having an ordinary skill in the art will recognize that embodiments of the disclosure can be practiced without these specific details. In some instances, well-known structures and processes are not described in detail to avoid unnecessarily obscuring embodiments of the present disclosure.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

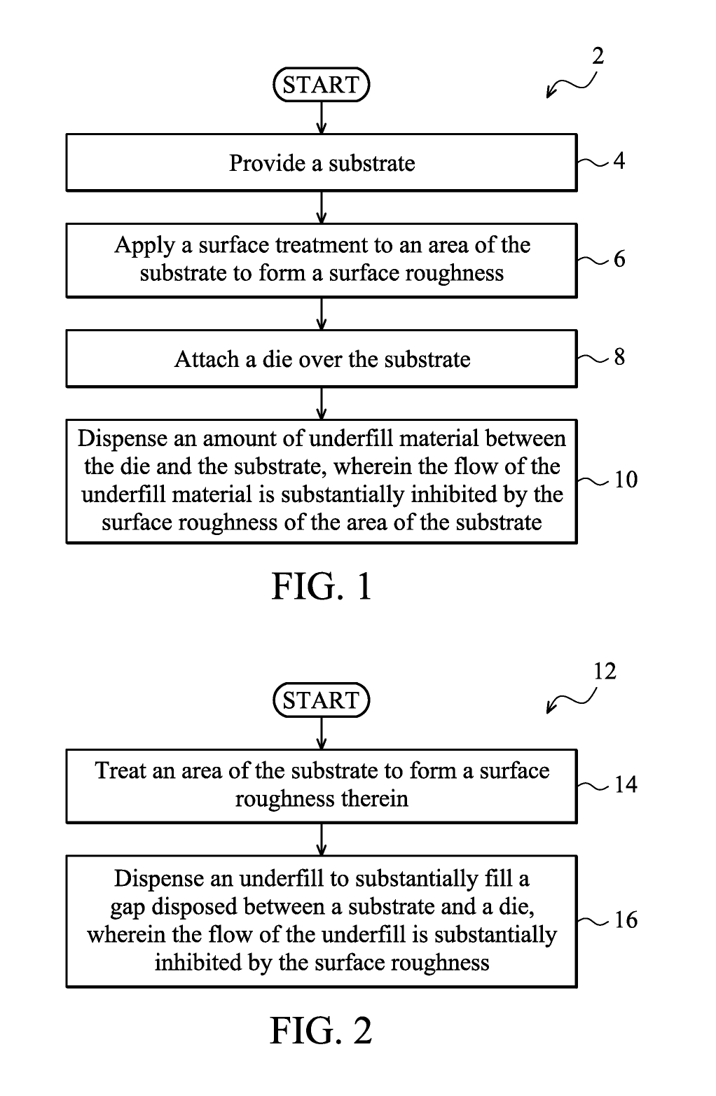

FIG. 1 is a flowchart of a method 2 for packaging a semiconductor device, according to various aspects of the present disclosure. Referring to FIG. 1, the method includes block 4, in which a substrate is provided. The method 2 includes block 6, in which an area of the substrate is surface treated to form a surface roughness. The method 2 includes block 8, in which a die is attached over the substrate. The method 2 includes block 10, in which an amount of underfill material is dispensed between the die and the substrate, wherein the flow of the underfill material is substantially inhibited by the surface roughness of the area of the substrate.

FIG. 2 is a flowchart of a method 12 for controlling underfill flow in a gap disposed between a substrate and a die, according to various embodiments of the present disclosure. The method 12 includes block 14, in which an area of the substrate is treated to form a surface roughness therein. The method 12 includes block 16, in which an underfill is dispensed to substantially fill a gap disposed between a substrate and a die, wherein the flow of the underfill is substantially inhibited by surface roughness.

It is understood that additional processes may be performed before, during, or after the blocks 4-10 shown in FIG. 1 to complete the packaging of the semiconductor device, but these additional processes are not discussed herein in detail for the sake of simplicity.

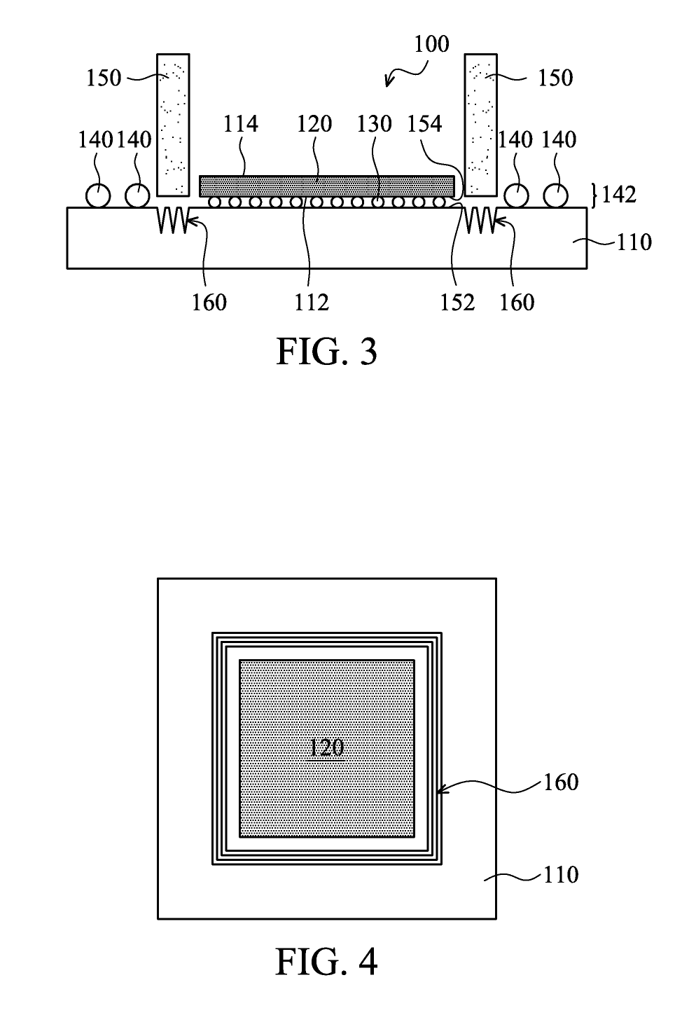

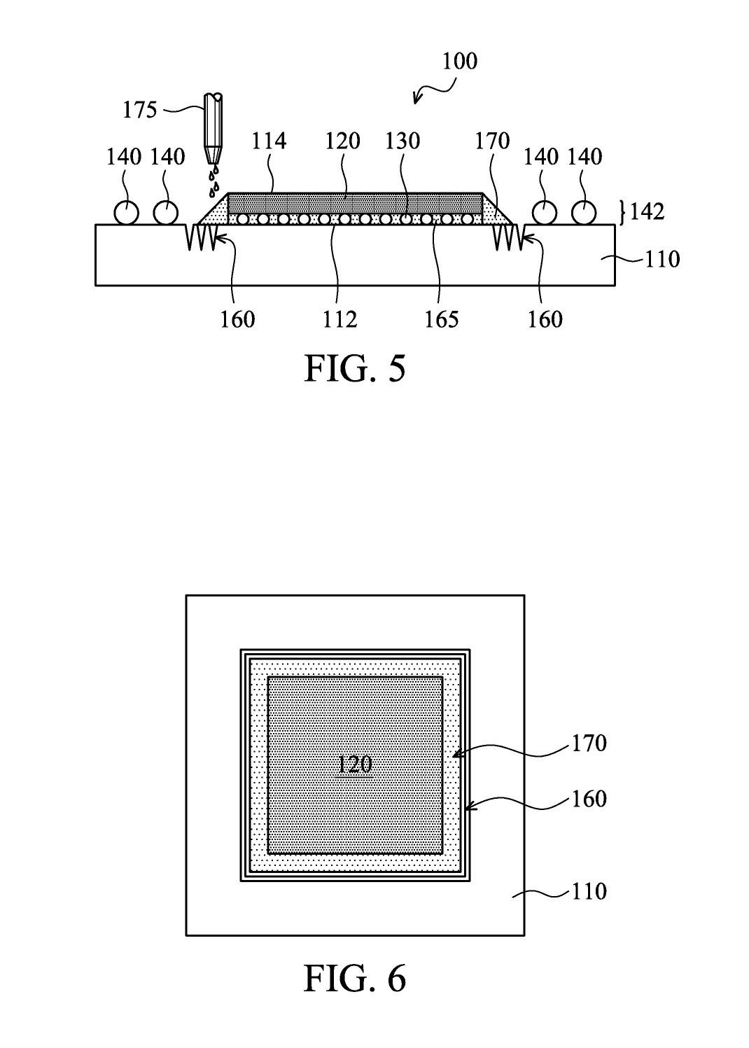

FIGS. 3 and 5 are diagrammatic fragmentary cross-sectional side views of a semiconductor device at various fabrication stages according to embodiments of the method 2 of FIG. 1. It is understood that FIGS. 3-6 have been simplified for a better understanding of the inventive concepts of the present disclosure. It should be appreciated that the materials, geometries, dimensions, structures, and process parameters described herein are exemplary only, and are not intended to be, and should not be construed to be, limiting to the invention claimed herein. Many alternatives and modifications will be apparent to those skilled in the art, once informed by the present disclosure.

Referring to FIG. 3, a semiconductor device assembly 100 is provided. FIG. 4 is a top view of the semiconductor device assembly 100 described with reference to FIG. 3. Referring to FIGS. 3 and 4, the semiconductor device assembly 100 is a flip chip assembly which includes a die (or an integrated circuit chip) 120 attached to a substrate (or a flexible film, or a board) 110 using solder bumps (or conductive bumps) 130, with a gap 142 formed between the die 120 and the substrate 110 filled with an underfill (or a polymeric material) 165 (not shown). The substrate 110 may contain routing traces, power/ground planes, vias, etc. (not shown) that electrically connect with the solder bumps 130. The die 120 is attached by reflowable solder bumps 130, which extend across the gap 142 and connect a plurality of contact pads (not shown) on the die 120 to a corresponding one of the plurality of terminal pads (not shown) on the substrate 110 both electrically and mechanically. The die 120, preferably formed of silicon, includes an active surface 112 and an inactive surface 114, which are planar and parallel to each other. Although the die 120 is shown to be mounted as a flip chip, other types of mounting such as upright with wire bonding are also contemplated. In a particular embodiment, the semiconductor device assembly 100 may be packaged as at least one of a chip scale package (CSP) and a ball grid array (BGA) package.

A surface area of the substrate 110, where a flow of the underfill is desired, is described as a dispensing surface 152. The dispensing surface 152 is in direct contact with the underfill. Similarly, a surface area of the die 120, where a flow of the underfill is desired, is described as a matching surface 154, which may be substantially the same as the active surface 112. The matching surface 154 is in direct contact with the underfill. In the depicted embodiment, the dispensing surface 152 is greater than the matching surface 154, the matching surface 154 being disposed above the dispensing surface 152. Thus, the gap 142 is formed between two surfaces that include the dispensing surface 152 of the substrate 110 and the matching surface 154 of the die 120.

When underfill is dispensed onto the substrate adjacent to the die, it then starts to spread out and move by capillary forces to fill the gap and encapsulate the solder bumps. In an aspect of the present disclosure, by roughening the surface as described below, the wetting characteristics are altered such that the underfill material will not flow as well on that roughened surface, so embodiments of the present invention prevent/mitigate the possibility of getting undesirable underfill over a selected protective area, such as conducting joints 140 (e.g., solder balls, solder bumps, metal pillars, or the like) of a neighboring device or a passive device. Further, as will be described in more detail below, by controlling the flow of the underfill, balanced fillet widths and heights can be formed thus reducing or eliminating high stress concentrations on the die.

Forming a roughened surface 160 on substrate 110 adjacent to the perimeter of the die 120 can be accomplished by a number of different surface treatments. In one embodiment, the substrate 110 is secured in a fixture and the top surface is masked to only expose the area which will be surface treated. Exposed areas on the mask will be exposed to surface treatment and the unexposed or masked areas will be protected. The exposed areas on the substrate 110 is media blasted and grit blasted. Abrasive media blasting and grit blasting are well known processes. Media blasting is usually a wet process, and grit blasting could be a wet or dry process. The materials used in either process could be the same, and can be chosen from a variety of materials, including glass beads, silica (SiO₂), alumina (Al₂O₃), and silicon carbide (SiC), as an example. The media blast parameters will depend on the media size, composition, hardness and substrate composition, and how those parameters will interact to achieve the desired roughness of the surface. An illustrative example, for a typical alumina ceramic substrate, would be silica media, with a 40 to 80 psi nozzle pressure, with the nozzle about 6 inches from the substrate surface, and at a 45 degrees incident angle to the surface. One skilled in the art would optimize the selection on media or grit blast parameters to achieve the desired surface roughness for a given substrate.

Another surface treatment is to expose the unmasked area to a chemical like hydroxide or hydrofluoric acid (HF). The selected chemical may be applied onto the exposed surface with a brush, or other methods such as spraying or syringe dispense. This is followed by a rinse with water or other solvent.

In yet another embodiment, the surface treatment exposes the unmasked area to a plasma source. Plasma is a well-known and useful tool/technology used in various applications such as in the fabrication and packaging of semiconductor devices. Surface modification and/or surface roughening of materials by plasma treatment is well-known for enhancing adhesion in underfill processes. In simplistic terms, a plasma source may be generated by applying electrical power across a pair of electrodes to a gas, the gas and the electrodes being enclosed in a plasma chamber.

In a particular embodiment, prior to the underfilling process, the area of the substrate 110 that is to receive plasma treatment is placed in the plasma chamber, near one of the electrodes. The plasma treatment is provided to masked off areas of the substrate 110 that is to be roughened. One skilled in the art would know the type of gas or gasses selected and the amount of the electrical power provide to determine the roughening of the plasma treated area. After receiving the plasma treatment, the object is removed from the plasma chamber and the mask and/or the protective covering is also removed. The use of the mask thereby enables providing plasma treatment to selective areas or surfaces of the substrate 110.

In yet another embodiment of the present disclosure, the area to be treated is exposed to a laser treatment. One skilled in the art would optimize the selection of the laser and the power to achieve the desired surface roughness for a given substrate. In one particular embodiment, the laser treatment could be UV laser (˜355 nm/10˜20 W), Green Laser (˜532 nm/50˜100 W), IR laser (˜1064 nm/20-30 W) and CO₂ laser (˜10.6 um/30 W). The treatment time would be from a few seconds to a few minutes.

In each of the above treatment methods, the roughened surface 160 is less wettable to an underfill, and will act as a barrier to the flow of the underfill, thus inhibiting the underfill from flowing outward to a protective area. The roughened surface 160 may include trenches or other similar surface roughness.

FIG. 5 is a cross-sectional view of a semiconductor device assembly described with reference to FIG. 3 undergoing a process of dispensing an underfill for filling a gap, according to an embodiment of the present disclosure. FIG. 6 is a top view of a semiconductor device assembly described with reference to FIG. 5. The underfill material 165 may comprise epoxy or polymer, although other materials may alternatively be used. In FIG. 5, a nozzle 175 of an underfill dispensing device (not shown) is used for dispensing the underfill 165 onto the substrate 110 adjacent to the perimeter of the die 120. Specifically, the nozzle 175 is positioned to dispense the underfill 165 between the dispensing surface 152 and the matching surface 154. The underfill 165 is pulled into the gap 142 by capillary forces and starts to spread out and move to fill the gap 142 and encapsulate the solder bumps 130. However, the flow of the underfill 165 is substantially inhibited when it encounters surface roughness 160. The wetting characteristics of the surface of the substrate 110 are altered in such a way that the underfill material 165 will not flow as well on that roughened surface. Therefore, embodiments of the present invention allows the flow rate or overflow of the underfill 165 to be controlled so that, for example undesirable underfill will not contact a selected protective area, such as conducting joints or solder balls 140 of a neighboring device (not shown). A benefit of this control is that solder balls 140 can be placed closer to die 120 ideal for advanced generation devices.

Due to surface tension, a small portion of the underfill 165 extends from an edge of the inactive surface 114 to an edge of the dispensing surface 152 to form a fillet 170. A balanced underfill fillet width and/or height can be achieved by determining the following:
1) Select a desired fillet width and/or height;
2) Select an amount and/or a volume of the underfill 165 to substantially match a volume of the gap 142, since the geometry of the gap 142 is known;
3) Determine a selective portion of the substrate surface to roughen based on the fillet width and/or height; and
4) Dispense the underfill 165 to substantially fill the gap 142, wherein the flow of the underfill 165 is substantially inhibited by the surface roughness.

Other methods of applying the underfill material 165 are also contemplated. Upon dispensing of the underfill 165, the semiconductor device assembly 100 is cured.

Various steps described above may be added, omitted, combined, altered, or performed in different orders. Embodiments of the present invention could be implemented at various stages in the semiconductor device assembly process. For example, it could be implemented at the substrate level, incoming to bond and assembly, or it could be implemented as the first step in the bond and assembly area.

Advantages of one or more embodiments of the present disclosure may include one or more of the following.

In one or more embodiments, balanced underfill fillet widths and/or heights can be formed, thus reducing or eliminating high stress concentrations on the die.

In one or more embodiments, the possibility of getting undesirable underfill over a protective area is prevented or mitigated. Therefore, conductive joints (e.g., solder balls, metal pillars, etc.) of neighboring devices or structures can be placed closer to the die, ideal for advanced generation devices.

In one or more embodiments, the adhesion between the underfill and the substrate is enhanced.

The present disclosure has described various exemplary embodiments. According to one embodiment, a method for controlling underfill flow in a gap disposed between a substrate and a die includes treating an area of the substrate to form a surface roughness therein. An underfill is dispensed to substantially fill the gap, wherein the flow of the underfill is substantially inhibited by the surface roughness.

According to another embodiment, a method of packaging a semiconductor device includes providing a substrate. A surface treatment is applied to an area of the substrate to form a surface roughness. A die is attached over the substrate. An amount of underfill material is dispensed between the die and the substrate, wherein the flow of the underfill material is substantially inhibited by the surface roughness of the area of the substrate.

According to yet another embodiment, a semiconductor device assembly includes a substrate having an area of the surface treated to form a surface roughness. A die is mounted on the substrate by a plurality of coupling members. An underfill to substantially fill a gap disposed between the substrate and the die, wherein a fillet width of the underfill is substantially limited to the area of surface roughness.

In the preceding detailed description, specific exemplary embodiments have been described. It will, however, be apparent to a person of ordinary skill in the art that various modifications, structures, processes, and changes may be made thereto without departing from the broader spirit and scope of the present disclosure. The specification and drawings are, accordingly, to be regarded as illustrative and not restrictive. It is understood that embodiments of the present disclosure are capable of using various other combinations and environments and are capable of changes or modifications within the scope of the claims.

1. A method for controlling underfill flow in a gap disposed between a substrate and a die, the method comprising:
treating an area of the substrate to form a surface roughness therein; and
dispensing an underfill to substantially fill the gap, wherein the flow of the underfill is substantially inhibited by the surface roughness.

2. The method of claim 1, wherein the treating includes exposing the area of the substrate to a laser, chemical, media blasting, or a plasma treatment.

3. The method of claim 2, wherein the chemical is selected from the group consisting of hydroxide and hydrofluoric acid.

4. The method of claim 2, wherein the media blasting material is selected from the group consisting of glass beads, SiO₂, Al₂O₃, and silicon carbide.

5. The method of claim 1, wherein the underfill is prevented from flowing over a protective area based on the surface roughness.

6. The method of claim 5, wherein the protective area includes a peripheral coupling joint of a neighboring device.

7. The method of claim 1, wherein the surface roughness comprises a plurality of trenches.

8. The method of claim 1, further comprising:
determining a desired fillet width of the underfill; and
determining a selective portion of the substrate based on the fillet width of the underfill, wherein the flow of the underfill is substantially limited to the selective portion of the substrate in response to the treating.

9. A method of packaging a semiconductor device, the method comprising:
providing a substrate;
applying a surface treatment to an area of the substrate to form a surface roughness;
attaching a die over the substrate; and
dispensing an amount of underfill material between the die and the substrate, wherein the flow of the underfill material is substantially inhibited by the surface roughness of the area of the substrate.

10. The method of claim 9, wherein the surface treatment comprises media blasting, laser treatment, plasma treatment, or the application of chemicals.

11. The method of claim 10, wherein the media blasting material is selected from the group consisting of glass beads, SiO₂, Al₂O₃, and silicon carbide.

12. The method of claim 10, wherein the chemicals are selected from the group consisting of hydroxide and hydrofluoric acid.

13. The method of claim 9, wherein the underfill material is prevented from flowing over a protective area due to the surface roughness.

14. The method of claim 13, wherein the protective area includes a peripheral coupling joint of a neighboring device.

15. The method of claim 9, wherein the surface roughness comprises a plurality of trenches.

16. The method of claim 9, wherein the die is coupled to the substrate by solder bumps.

17.-20. (canceled)

21. A method of packaging a semiconductor device, the method comprising:
forming a first electrical connection on a surface of a substrate;
removing portions of the surface to form a roughened region;
electrically and physically connecting a second electrical connection of a die to the first electrical connection; and
dispensing an underfill material between the die and the surface of the substrate; and
inhibiting flow of the underfill material across the surface of the substrate through placement of the roughened region.

22. The method of claim 21 wherein the step of removing portions of the surface comprises a process selected from the group consisting of abrasion, chemical etching, and plasma etching.

23. The method of claim 21 wherein the step of removing portions of the surface to form a roughened region comprises forming a plurality of trenches in the surface.

24. The method of claim 21 further comprising curing the underfill material.
